(19) United States
(12) Patent Application Publication
(10) Pub. No.: US 2026/0344146 A1
(43) Pub. Date: Oct. 29, 2026

(54) DISPLAY PANEL AND DISPLAY DEVICE

(71) Applicants: BOE MLED Technology Co., Ltd., Beijing (CN); BOE Technology Group Co., Ltd., Beijing (CN)

(72) Inventors: Lili WANG, Beijing (CN); Shanshan FENG, Beijing (CN); Chao LIU, Beijing (CN); Jingping ZHAO, Beijing (CN); Ming ZHAI, Beijing (CN); Qi QI, Beijing (CN)

(21) Appl. No.: 18/841,532

(22) PCT Filed: Dec. 14, 2023
(86) PCT No.: PCT/CN2023/138735

§ 371 Date: Aug. 26, 2024

(51) Int. Cl. H10H 29/49; H10H 29/41

(52) U.S. Cl. CPC H10H 29/49; H10H 29/41

(57) ABSTRACT

Disclosed is a display panel and a display device, belonging to the field of display technologies. The display panel includes a substrate, a first surface wiring, a plurality of electrode structures, a side wiring, and a first retaining wall structure. The first retaining wall structure is disposed at least between any two adjacent electrode structures, and at least two of a plurality of cross-sections of the first retaining wall structure parallel to the first surface have different areas. The cross-sections of the first retaining wall structure having different areas are formed by laser etching, such that at least a portion of conductive material accumulated at the first retaining wall structure during the formation of the side wiring is removed by the laser etching to avoid the portion of the accumulated conductive material from causing a short circuit of adjacent electrode structures, and thus the yield of the display panel is improved.

### CROSS-REFERENCE TO RELATED APPLICATIONS

The present disclosure is a U.S. national phase application based on PCT/CN2023/138735, filed on Dec. 14, 2023, the content of which is herein incorporated by reference in its entirety.

### TECHNICAL FIELD

The present disclosure relates to the field of display technologies, and in particular, relates to a display panel and a display device.

### BACKGROUND

A display panel is a device with a display function.

### SUMMARY

Embodiments of the present disclosure provide a display panel and a display device. The technical solutions are described as follows.

In one aspect, a display panel is provided. The display panel includes:
a substrate having a first surface and a second surface which are opposite, and a plurality of side surfaces connected to the first surface and the second surface, the first surface including a display region and a peripheral region surrounding the display region; and
a first surface wiring disposed on the display region of the first surface, an electrode structure disposed on the peripheral region of the first surface, and a plurality of side wirings disposed on at least one of the plurality of side surfaces;
wherein one end of each of the plurality of side wirings is electrically connected to the electrode structure and another end extends sequentially through the first surface and the at least one of the plurality of side surfaces to the second surface, and the electrode structure is further electrically connected to the first surface wiring; and
a plurality of the electrode structures are defined and are spaced apart along a first direction, the first direction being a direction parallel to the at least one of the plurality of side surfaces; and
the display panel further includes a first retaining wall structure is disposed at least between any two adjacent electrode structures, wherein at least two of a plurality of cross-sections of the first retaining wall structure parallel to the first surface have different areas;
wherein a cross-section with a smallest area of the plurality of cross-sections is a first cross-section, an orthographic projection of the first cross-section on the first surface has a first contour, and an orthographic projection of the first surface wiring on the first surface has a second contour, a minimum distance d1 between the first contour and the second contour in a second direction is not less than 10 μm, the second direction being perpendicular to the first direction.

In some embodiments, in the second direction, the first contour and the second contour satisfy that a ratio of d2 to d3 is greater than ½ and less than 3, wherein the d2 is a minimum distance between a first position of the first contour and the second contour, and the d3 is a minimum distance between an edge of the electrode structure away from the side wiring and the second contour, the first position being a position of the first contour which is furthest away from the second contour.

In some embodiments, in the second direction, the first contour and the second contour satisfy that the ratio of d2 to d3 is greater than 1 and less than 3.

In some embodiments, the first retaining wall structure includes a plurality of stacked film layers, a thickness of the plurality of stacked film layers in a direction perpendicular to the substrate ranging from 3 μm to 6 μm.

In some embodiments, the first retaining wall structure includes a protective layer and at least one film layer, wherein the protective layer is disposed on the substrate where the first surface wiring is formed, and an edge of the protective layer close to the side wiring is disposed on a side of the first surface wiring close to the side wiring, and the at least one film layer is stacked on the protective layer.

In some embodiments, in the second direction, a position of the protective layer closest to the side surface is a second position, and a position of the at least one film layer closest to the side surface is a third position; wherein
in the second direction, the second position and the third position are flush, or, in the second direction, the third position is disposed on a side of the second position close to the side surface.

In some embodiments, in a case that, in the second direction, the third position is disposed on the side of the second position close to the side surface, a specified distance is present between the third position and the second position in the second direction, the specified distance ranging from 20 μm to 100 μm.

In some embodiments, the first retaining wall structure includes a target film layer, a thickness of the target film layer in a direction perpendicular to the substrate ranging from 3 μm to 6 μm.

In some embodiments, in the second direction, a minimum distance between a first position of the first contour and the second contour ranges from 50 μm to 150 μm, the first position being a position of the first contour furthest away from the second contour.

In some embodiments, the display panel further includes a second retaining wall structure, wherein the second retaining wall structure is disposed on a side of the first retaining wall structure away from the side wiring, and the second retaining wall structure covers an edge of the first surface wiring close to the side wiring.

In some embodiments, the first retaining wall structure is connected to the second retaining wall structure.

In some embodiments, a spacing is present between the first retaining wall structure and the second retaining wall structure.

In some embodiments, the spacing between the first retaining wall structure and the second retaining wall structure ranges from 10 μm to 110 μm.

In another aspect, a display device is provided. The display device includes a display structure and the display panel as described in the above aspect, wherein the display structure is disposed on the display panel.

The beneficial effects of the technical solutions provided by the embodiments of the present disclosure include at least the following:

A display panel including a first retaining wall structure and a display device are provided. In the display panel, the first retaining wall structure is disposed at least between any two adjacent electrode structures, and at least two of a plurality of cross-sections of the first retaining wall structure parallel to a first surface have different areas. The cross-sections of the first retaining wall structure having different areas are formed by laser etching, such that at least a portion of the conductive material accumulated at the first retaining wall structure during the formation of the side wiring can be removed by laser etching to avoid the portion of the accumulated conductive material from causing a short circuit of the adjacent electrode structures, and thus the yield of the display panel is improved.

### BRIEF DESCRIPTION OF DRAWINGS

To describe the technical solutions in the embodiments of the present disclosure more clearly, the following briefly introduces the accompanying drawings required for describing the embodiments. Apparently, the accompanying drawings in the following description illustrate merely some embodiments of the present disclosure, and persons of ordinary skill in the art may still derive other drawings from these accompanying drawings without creative efforts.

FIG. 1 is a schematic structure diagram of a top view of a display panel according to some embodiments of the present disclosure;

FIG. 2 is an enlarged schematic diagram of a partial structure of the display panel shown in FIG. 1;

FIG. 3 is an enlarged schematic diagram of another partial structure of the display panel shown in FIG. 1;

FIG. 4 is a schematic structure diagram of a cross-section of the display panel shown in FIG. 1;

FIG. 5 is a schematic structure diagram of a top view of a partial structure of another display panel according to some embodiments of the present disclosure;

FIG. 6 is a schematic structure diagram of a top view of a partial structure of another display panel according to some embodiments of the present disclosure;

FIG. 7 is a schematic structure diagram of a cross-section of the display panel shown in FIG. 2;

FIG. 8 is a schematic structure diagram of a top view of a partial structure of another display panel according to some embodiments of the present disclosure;

FIG. 9 is a schematic structure diagram of another cross-section of the display panel shown in FIG. 2;

FIG. 10 is a schematic structure diagram of another cross-section of the display panel shown in FIG. 2;

FIG. 11 is a schematic structure diagram of a top view of another display panel according to some embodiments of the present disclosure;

FIG. 12 is a schematic structure diagram of a cross-section of the display panel shown in FIG. 11;

FIG. 13 is a schematic structure diagram of a cross-section of a partial structure of another display panel according to some embodiments of the present disclosure;

FIG. 14 is a schematic structure diagram of a top view of a partial structure of another display panel according to some embodiments of the present disclosure;

FIG. 15 is a schematic structure diagram of a cross-section of the display panel shown in FIG. 14;

FIG. 16 is a schematic structure diagram of a top view of a partial structure of another display panel according to some embodiments of the present disclosure;

FIG. 17 is a schematic structure diagram of a cross-section of a partial structure of another display panel according to some embodiments of the present disclosure; and

FIG. 18 is a schematic structure diagram of a cross-section of a partial structure of another display panel according to some embodiment of the present disclosure.

Specific embodiments of the present disclosure have been shown by means of the above-described accompanying drawings, which will be described in more detail hereafter. These accompanying drawings and textual descriptions are not intended to limit the scope of the present disclosure in any way, but rather to illustrate the concepts of the present disclosure for those skilled in the art by reference to particular embodiments.

### DETAILED DESCRIPTION

For clearer descriptions of the objectives, technical solutions, and advantages of the present disclosure, embodiments of the present disclosure are described in detail hereinafter with reference to the accompanying drawings.

The display panel includes a substrate, a first surface wiring provided on a first surface of the substrate, a side wiring provided on a side surface of the substrate, an electrode structure, and a retaining wall structure. One end of the side wiring is electrically connected to the electrode structure, and the other end of the side wiring extends sequentially through the first surface and the side surface to a second surface. The retaining wall structure is disposed between two adjacent electrode structures on the first surface, such that a conductive material of the side wiring can be blocked from entering a display region.

However, the conductive material forming the side wiring can accumulate at an edge of the retaining wall structure close to the side surface, which can cause a short circuit of adjacent electrode structures, and thus cause a lower yield of the display panel.

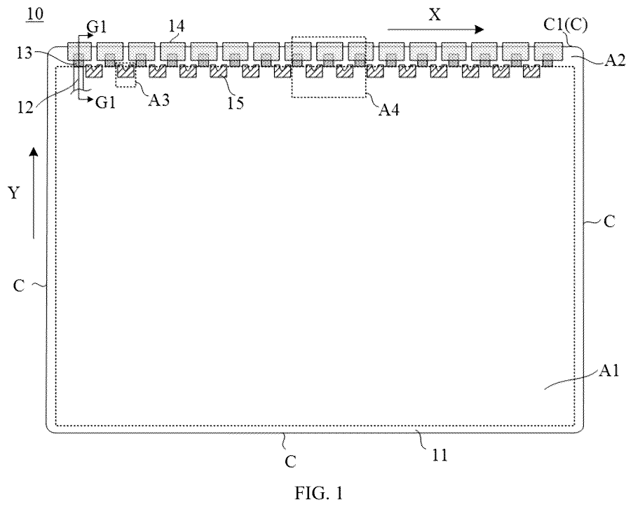

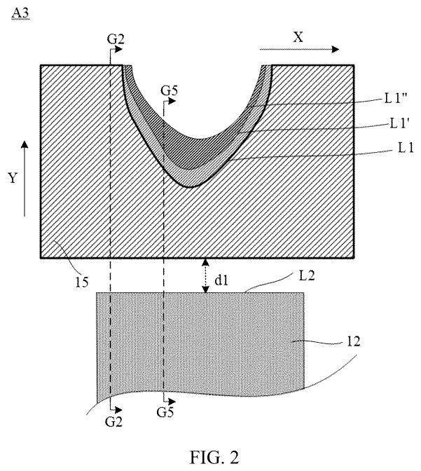

The embodiments of the present disclosure provide a display panel. Referring to FIG. 1 and FIG. 2, FIG. 1 is a schematic structure diagram of a top view of a display panel according to some embodiments of the present disclosure, and FIG. 2 is an enlarged schematic diagram of a region A3 in the display panel shown in FIG. 1. The display panel 10 includes a substrate 11, a first surface wiring 12, an electrode structure 13, a plurality of side wirings 14, and a first retaining wall structure 15.

The substrate 11 has a first surface A and a second surface B which are opposite, and a plurality of side surfaces C connected to the first surface A and the second surface B. The first surface A includes a display region A1 and a peripheral region A2 surrounding the display region A1.

The first surface wiring 12 is disposed on the display region A1 of the first surface A, the electrode structure 13 is disposed on the peripheral region A2 of the first surface A, and the plurality of side wirings 14 are disposed on at least one side surface C1 of the plurality of side surfaces C.

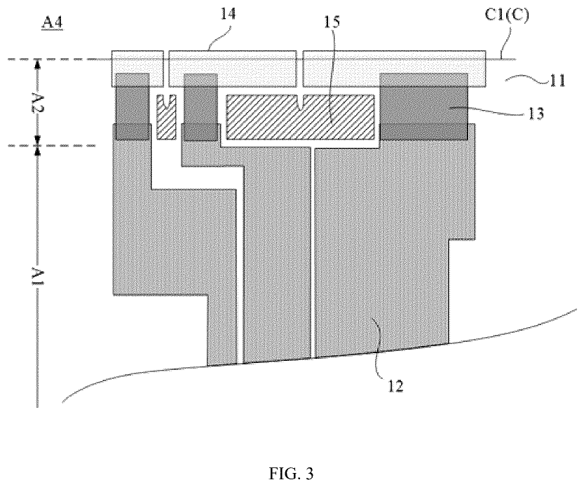

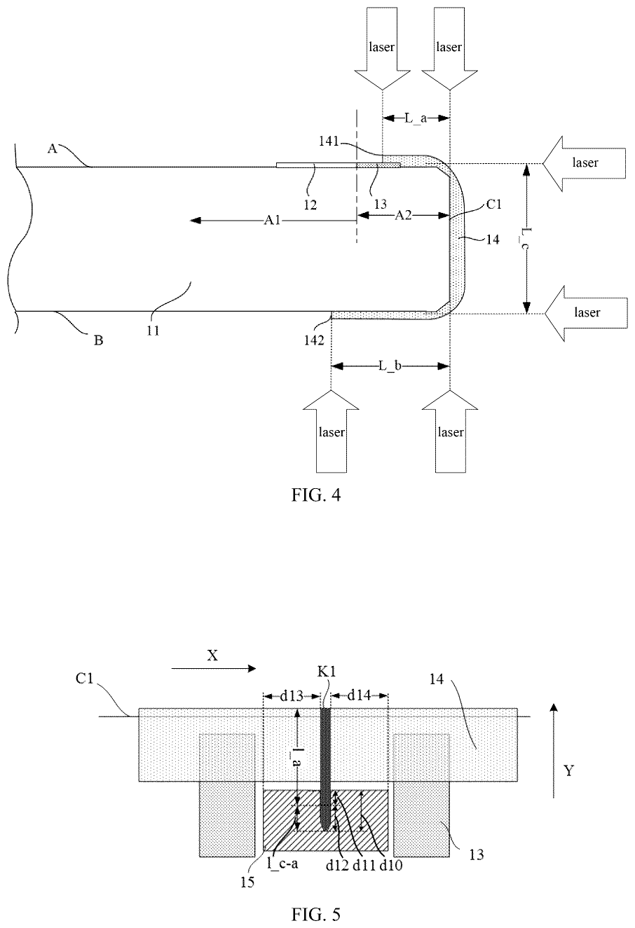

In addition, referring to FIG. 3 and FIG. 4, FIG. 3 is an enlarged schematic diagram of a region A4 of the display panel shown in FIG. 1 (for clarity of the schematic diagram, FIG. 3 illustrates only the first surface wiring 12, and the display region A1 also includes other film layer structures, which is not limited in the present disclosure), and FIG. 4 is a schematic structure diagram of a cross-section of the display panel shown in FIG. 1 (FIG. 4 may be a schematic structure diagram of a cross-section of the display panel shown in FIG. 1 at G1-G1), one end 141 of each of the side wirings 14 is electrically connected to the electrode structure 13, and another end 142 extends sequentially through the first surface A and the at least one side surface C1 to the second surface B, and the electrode structure 13 is also electrically connected to the first surface wiring 12. That is, each of the side wirings 14 includes a portion on the first surface A, a portion on the at least one side surface C1, and a portion on the second surface B.

A plurality of the electrode structures 13 are defined and are spaced apart along a first direction X, the first direction X being a direction parallel to at least one side surface C1 of the plurality of side surfaces C. The first retaining wall structure 15 is disposed at least between any two adjacent electrode structures 13. At least two of a plurality of cross-sections of the first retaining wall structure 15 parallel to the first surface A have different areas. The cross-sections of the first retaining wall structure having different areas are formed by laser etching, and before the laser etching, the areas of the plurality of cross-sections of the first retaining wall structure 15 parallel to the first surface A are substantially the same.

A cross-section with the smallest area of the plurality of cross-sections is a first cross-section. An orthographic projection of the first cross-section on the first surface A has a first contour L1, and an orthographic projection of the first surface wiring 12 on the first surface A has a second contour L2. A minimum distance d1 between the first contour L1 and the second contour L2 in a second direction Y is not less than 10 μm, the second direction Y is perpendicular to the first direction X. In this way, a certain distance is present between the first surface wiring 12 and the first retaining wall structure 15, such that the damage to the first surface wiring 12 can be avoided during laser etching of the first retaining wall structure 15.

Referring to FIG. 2, the plurality of cross-sections also includes a second cross-section and a third cross-section. An orthographic projection of the second cross-section on the first surface A has a contour L1′, and an orthographic projection of the third cross-section on the first surface A has a contour L1″. It can be seen that an area of the third cross-section is greater than an area of the second cross-section, and the area of the second cross-section is greater than an area of the first cross-section.

It should be noted that FIG. 1 illustrates a case where the side wiring 14 is disposed on the side surface C1. In the embodiments of the present disclosure, the side wiring 14 may also be disposed on one or more other side surfaces. Correspondingly, the first retaining wall structure 15 may also be disposed on the peripheral region A2 close to other side surfaces.

In summary, the embodiments of the present disclosure provide a display panel including a first retaining wall structure and a display device. In the display panel, the first retaining wall structure is disposed at least between any two adjacent electrode structures, and at least two of the plurality of cross-sections of the first retaining wall structure parallel to the first surface have different areas. The cross-sections of the first retaining wall structure having different areas are formed by laser etching, such that at least a portion of the conductive material accumulated at the first retaining wall structure during the formation of the side wiring can be removed by laser etching to avoid the portion of the accumulated conductive material from causing a short circuit of the adjacent electrode structures, and thus the yield of the display panel is improved.

The display panel provided by the embodiments of the present disclosure may include a mini light-emitting diode (mini LED) display panel and a micro light-emitting diode (micro LED) display panel. In the embodiments of the present disclosure, small-sized mini LED display panels or micro LED display panels may be spliced together to achieve an oversized display panel. Exemplarily, the display panel provided by the embodiments of the present disclosure may include the side wiring. The side wiring may bind and connect a light-emitting element of the first surface to a circuit board of the second surface, such that the circuit board is not necessarily arranged in the peripheral region, and thus the effect of narrowing the peripheral region can be achieved. In this way, the structure is applied to a display device including a plurality of display panels spliced together, a splicing seam of two adjacent display panels can also be narrowed to enhance the display effect. The splicing seam refers to a region between the display regions of the two adjacent display panels that cannot be displayed.

In an exemplary embodiment, referring to FIG. 1 and FIG. 4, the substrate 11 may be used to carry film layers or structures in the display panel 10. The material of the substrate 11 may include any of glass, quartz, plastic, polymethyl methacrylate (PMMA), and the like. The first surface wiring 12 disposed on the display region A1 is electrically connected to an electrical element, and one end of the first surface wiring 12 close to the peripheral region A2 is electrically connected to the electrode structure 13. The electrode structure 13 may be electrically connected to the first surface wiring 12 and the side wiring 14. One end 141 of the side wiring 14 is electrically connected to the electrode structure 23, and the other end 142 of the side wiring 14 may be electrically connected to a control assembly disposed on the second surface B. Exemplarily, the electrical element may include a light-emitting element, and the control assembly may include a circuit board, such that the side wiring 14 may transmit an electrical signal provided by the control assembly disposed on the second surface B to an element or a structure on the first surface A.

In an exemplary embodiment, the side wiring 14 may be prepared by the following processes.
1) The display region A1 of the first surface A is shielded by using a cover plate to protect the display region A1 where the side wiring 14 does not need to be formed, and the cover plate may be a flat structure prepared from a rigid material.
2) The conductive material layer (such as a metal layer) is formed on the peripheral region A2 of the first surface A, the side surface C of the substrate 11, and the second surface B of the substrate 11. The process for forming the conductive material layer may include sputter.
(3) The side wiring 14 is formed by etching the conductive material layer. The conductive material layer may be laser etched by an ultraviolet (UV) ultrashort pulsed laser. The laser etching includes etching the conductive material layer on the first surface A along a path L_a, etching the conductive material layer on the side surface C along a path L_c, and etching the conductive material layer on the second surface B along a path L_b.

The first retaining wall structure 15 is disposed at least between any two adjacent electrode structures 13, and the first retaining wall structure 15 is formed before the side wiring 14. The shapes of the plurality of cross-sections of the first retaining wall structure 15 parallel to the first surface may be approximately equal rectangles before the side wiring 14 is formed. During forming the conductive material layer of the side wiring 14, a boundary of the first retaining wall structure 15 close to the side surface C1 may serve as an alignment marking line for arranging a baffle to avoid the formation of the conductive material layer on the display region A1. In addition, it may be appreciated in conjunction with FIG. 4 and FIG. 5 that, in the process of forming the side wiring 14 by laser etching, an etching channel is between two adjacent side wirings 14. Taking a portion of the side wiring 14 disposed on the first surface A as an example, a sub-etching channel K1 is between the two adjacent side wirings 14. The sub-etching channel K1 includes a portion (1_a) formed after the laser performs an etching of the conductive material layer on the first surface A along the path L_a, wherein the length of L_a is greater than or equal to the size of the side wiring 14 in the second direction Y. The sub-etching channel K1 also includes a portion (1_c-a) formed by the laser irradiating the first surface A due to process accuracy or the like when etching the conductive material layer disposed on the side surface C along the path L_c. Both the laser traveling along the path L_a and the laser traveling along the path L_c may interfere with the first retaining wall structure 15, thereby changing the morphology of the first retaining wall structure 15. In this way, an end, close to the side surface C1, of the first retaining wall structure 15 has the structure indicated in FIG. 2, thereby effectively avoiding a short-circuit of the two adjacent electrode structures 13 by the sub-etching channel K1. A size d11 of a portion of 1_a being overlapped with the first retaining wall structure 15 in the second direction Y may range from 0 μm to 50 μm, and exemplarily, d11 is 15 μm. A size d12 of a portion of 1_c-a being overlapped with the first retaining wall structure 15 in the second direction Y may range from 10 μm to 50 μm, and exemplarily, d12 is 15 μm.

The shape of an end of the sub-etching channel K1 away from the side surface may be curved. A size d10 of a portion of the sub-etching channel K1 being overlapped with the first retaining wall structure 15 in the second direction Y may range from 10 μm to 50 μm, and exemplarily, d10 is 30 μm. In the first direction X, the first retaining wall structure 15 may include an edge L6 and an edge L7 which are opposite. A minimum distance between the sub-etching channel K1 and the edge L6 is d13, and a minimum distance between the sub-etching channel K1 and the edge L7 is d14, with both d13 and d14 being greater than 15 μm, thereby avoiding the laser damaging other film layers outside the first retaining wall structure 15 due to alignment bias when d13 and d14 are too small. Exemplarily, d13 and d14 may be the same, i.e., the sub-etching channel K1 is disposed in the center of the first retaining wall structure 15 in the first direction X.

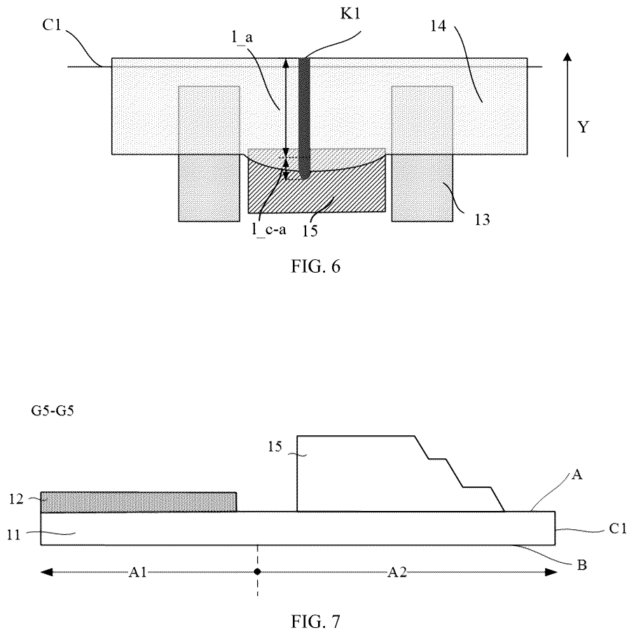

FIG. 6 is a schematic structure diagram of a top view of a partial structure of another display panel according to some embodiments of the present disclosure. In the case that a portion of the conductive material climbs up to the surface of the first retaining wall structure 15 due to preparation tolerances or the like during the formation of the conductive material layer, and a length of the sub-etching channel K1 along the second direction Y is greater than a maximum length of the conductive material layer along the second direction Y, it can be ensured that the conductive material layer to be formed into the side wiring 14 is disconnected to avoid a short circuit.

The first retaining wall structure in the display panel provided in the embodiments of the present disclosure has at least two of the plurality of cross-sections parallel to the first surface having different areas. Referring to FIG. 2 and FIG. 7, FIG. 7 is a schematic diagram of a cross-section structure of the display panel shown in FIG. 2 (FIG. 7 is a schematic diagram of a cross-section structure of the display panel shown in FIG. 2 at G5-G5, and G5-G5 is a position of the laser etching). As the laser extends to the first retaining wall structure 15 and forms an etching channel, and the etching channel makes at least two of the plurality of cross-sections of the first retaining wall structure 15 parallel to the first surface have different areas, a cross-section structure of the first retaining wall structure 15 may present an irregular step-like structure. In an exemplary embodiment, the first retaining wall structure 15 may include a plurality of stacked film layers. The plurality of stacked film layers may be prepared from different materials, and the different materials themselves have differences in laser absorption rates, such that at least two of the plurality of cross-sections of the first retaining wall structure 15 parallel to the first surface have different areas. On the other hand, as a position on the first retaining wall structure 15 closer to the substrate 11 is farther away from the laser, the energy density of the laser received at the position on the first retaining wall structure 15 closer to the substrate 11 is lower, an area of a cross-section of the first retaining wall structure closer to the substrate 11 among the plurality of cross-sections parallel to the first surface is relatively smaller.

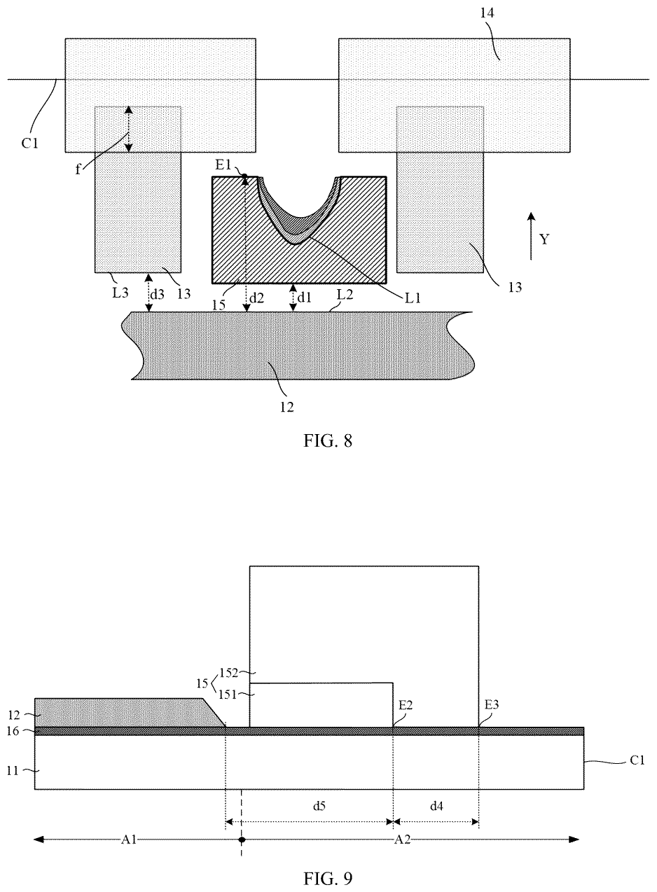

In an exemplary embodiment, referring to FIG. 8, FIG. 8 is a schematic structure diagram of a top view of a partial structure of another display panel according to some embodiments of the present disclosure. In the second direction Y, d2 is a minimum distance between a first position E1 of the first contour L1 and the second contour L2, and d3 is a minimum distance between an edge L3 of the electrode structure 13 away from the side wiring 14 and the second contour L2. In the second direction Y, the first position E1 is a position of the first contour L1 furthest away from the second contour L2. Exemplarily, the first position E1 may be a position which is furthest from the second contour L2 in an edge of the first retaining wall structure 15 close to the side surface C1 in the second direction Y before the side wiring 14 is formed.

The relative position between the first position E1 of the first contour L1 and the edge L3 of the electrode structure 13 away from the side wiring 14 can be determined by the size relationship between d2 and d3. Exemplarily, FIG. 8 illustrates a case where d2 is greater than d3, in which the first position E1 of the first contour L1 is disposed on a side, close to the side surface, of the edge L3 of the electrode structure 13 away from the side wiring 14. That is, the first position E1 of the first contour L1 is closer to the side surface, such that the distance of the laser etching in the second direction Y is shortened. In the second direction Y, the minimum distance d2 between the first position E1 of the first contour L1 and the second contour L2 may range from 50 μm to 150 μm. The d2 is greater than or equal to 50 μm to prevent the laser etching from damaging the first surface wiring 12, and d2 is less than or equal to 150 μm to make the space of the peripheral region occupied by the first retaining wall structure 15 not be too large. In the case that the first retaining wall structure 15 is applied to a display device including a plurality of display panels spliced together, the first retaining wall structure 15 can be avoided from causing splicing seams between the plurality of display panels to be too large, and thus the display effect can be improved. In the second direction Y, the minimum distance d3 between the edge L3 of the electrode structure 13 away from the side wiring 14 and the second contour L2 may range from 50 μm to 100 μm. In addition, the overlapping size f of the side wiring 14 and the electrode structure 13 is at least 40 μm, such that the stability of the electrical connection between the side wiring 14 and the electrode structure 13 can be ensured. In addition, d2 may be less than d3, in which the first position E1 of the first contour L1 is disposed on a side, away from the side surface, of the edge L3 of the electrode structure 13 away from of the side wiring 14. That is, the edge L3 of the electrode structure 13 away from the side wiring 14 is closer to the side surface.

In some embodiments, in the second direction Y, the first contour LI and the second contour L2 can satisfy that a ratio of d2 to d3 is greater than ½ and less than 3, such that the first position E1 of the first contour L1 can be avoided to be too close to the side wiring 14 or the second contour L2, and thus the conductive material can be avoided from sputtering onto the surface of the first retaining wall structure 15 away from the substrate in the case that the first retaining wall structure 15 is too close to the side wiring 14. In this way, it is ensured that the first retaining wall structure 15 can effectively block a boundary of the conductive material. The boundary of the conductive material is also a boundary of the side wiring 14 away from the side surface C1. In addition, an increased risk of water vapor intrusion into the first surface wiring 12 can be avoided in the case that the first contour L1 is too close to the second contour L2.

Based on the above range, in the second direction Y, the first contour L1 and the second contour L2 may satisfy that the ratio of d2 to d3 is greater than 1 and less than 3. In this way, not only can the distance of the laser etching in the second direction Y be shortened, but also an increased risk of water vapor intrusion into the first surface wiring 12 when the first contour L1 is too close to the second contour L2 can be avoided.

The film layers that may be included in the first retaining wall structure are described as follows.

The first retaining wall structure is a multi-layer structure or a single-layer structure. In an exemplary embodiment, the first retaining wall structure may include a plurality of stacked film layers. The thickness of the plurality of stacked film layers in a direction perpendicular to the substrate ranges from 3 μm to 6 μm, which ensures that the first retaining wall structure can block the conductive material of the side wiring and does not cause the thickness of the first retaining wall structure to be too great to affect a total thickness of the display panel. Referring to FIG. 2 and FIG. 9, FIG. 9 is a schematic structure diagram of another cross-section of the display panel shown in FIG. 2 (FIG. 9 may be a schematic structure diagram of a cross-section of the display panel shown in FIG. 2 at G2-G2, with the first retaining wall structure 15 at G2-G2 being not etched). The first retaining wall structure 15 may include a protective layer 151 and at least one film layer 152 which are sequentially stacked along a direction away from the substrate 141. The protective layer 151 is disposed on the substrate 11 formed with the first surface wiring 12, and an edge of the protective layer 151 close to the side surface C1 is disposed on a side of the first surface wiring 12 close to the side surface C1, and the at least one film layer 152 is stacked on the protective layer 151.

At least one film layer 152 is stacked on the protective layer 151. The at least one film layer 152 can be used to increase the thickness of the first retaining wall structure 15 in the direction perpendicular to the substrate 11. The total thickness of the protective layer 151 and the at least one film layer 152 in the direction perpendicular to the substrate ranges from 3 μm to 6 μm, which allows the conductive material to be disposed on the edge of the first retaining wall structure 15 close to the side surface. In this way, the conductive material can be avoided from sputtering to the side of the first retaining wall structure 15 away from the substrate 11, such that the first retaining wall structure 15 can effectively block the conductive material of the side wiring 14 from entering the display region.

In addition, between the substrate 11 and the first surface wiring 12, the display panel 10 may also include a first buffer layer 16. The first buffer layer 16 may increase the bonding force between the first surface wiring 12 and the substrate 11, such that the first surface wiring 12 may be prevented from peeling off. The material of the first buffer layer 16 may include silicon nitride (SiNx), and/or, silicon oxide (SiOx).

In some embodiments, in the second direction Y, a position of the protective layer 151 closest to the side surface C1 is a second position E2. Exemplarily, the second position E2 may be a position, in the second direction Y, closest to the side surface C1 in an edge of the protective layer 151 close to the side surface C1 before the side wiring 14 is formed. In the second direction Y, a position of the at least one film layer 152 closest to the side surface C1 is a third position E3. Exemplarily, the third position E3 may be a position, in the second direction Y, closest to the side surface C1 in an edge of the at least one film layer 152 close to the side surface C1 before the side wiring 14 is formed. The relative positions of the second position E2 and the third position E3 include various cases.

Exemplarily, as shown in FIG. 9, the third position E3 may be disposed on a side of the second position E2 close to the side surface. At this time, at least one film layer 152 is stacked to cover the protective layer 151, which helps to prevent the protective layer 151 from peeling off. The third position E3 has a specified distance d4 from the second position E2 in the second direction Y. The specified distance d4 may range from 20 μm to 100 μm. Referring to FIG. 8, as the minimum distance d2 between the first position E1 of the first contour L1 and the second contour L2 may range from 50 μm to 150 μm, by making the specified distance d4 greater than 20 μm, it can be ensured that a distance d5 between the second position E2 of the protective layer 151 and an edge of the first surface wiring 12 close to the side surface C1 is at least 30 μm, and thus water and oxygen can be prevented from corroding the first surface wiring 12. By making the specified distance d4 less than 100 μm, it can avoid the first retaining wall structure 15 being too close to the side surface causing the conductive material of the side wiring 14 to be sputtered onto the side of the first retaining wall structure 15 away from the substrate 11, thereby ensuring that the first retaining wall structure 15 can effectively block the conductive material. In addition, based on the above d2 and d4, the distance d5 between the second position E2 of the protective layer 151 and the edge of the first surface wiring 12 close to the side surface C1 may range from 30 μm to 50 μm.

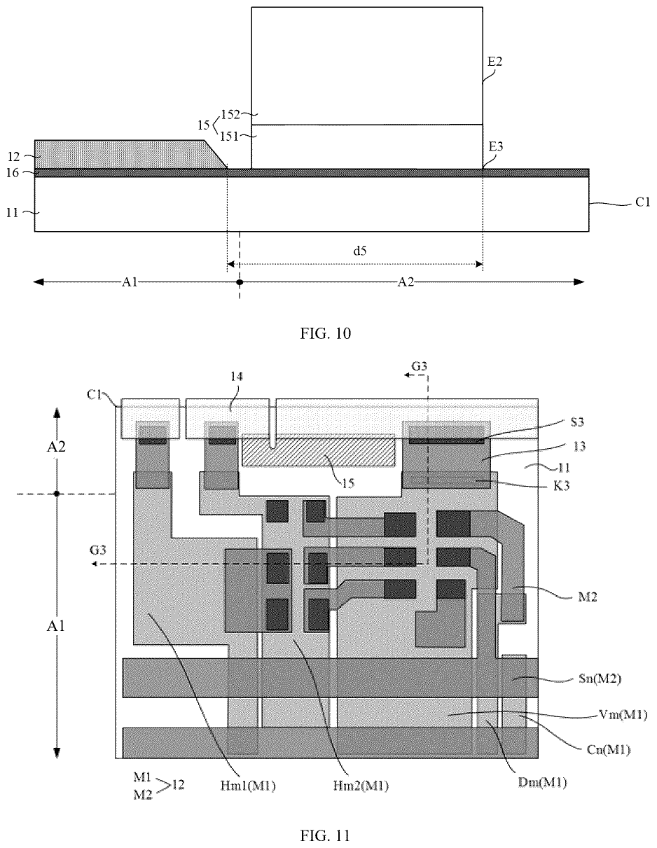

The relative positions of the second position E2 and the third position E3 include another case. As shown in FIG. 10, FIG. 10 is a schematic structure diagram of another cross-section of the display panel shown in FIG. 2 (FIG. 10 may be a schematic structure diagram of a cross-section of the display panel shown in FIG. 2 at G2-G2), the second position E2 and the third position E3 may also be flush, i.e., d4 may be equal to 0.

The display region of the display panel provided by the embodiments of the present disclosure may include a plurality of film layers that are stacked. The film layers may constitute various structures in the display panel to realize a display function of the display panel. In the case that the first retaining wall structure includes a plurality of stacked film layers, the plurality of stacked film layers in the first retaining wall structure may be of the same layer as some of the film layers in the display region to achieve the effect of reducing the composition process.

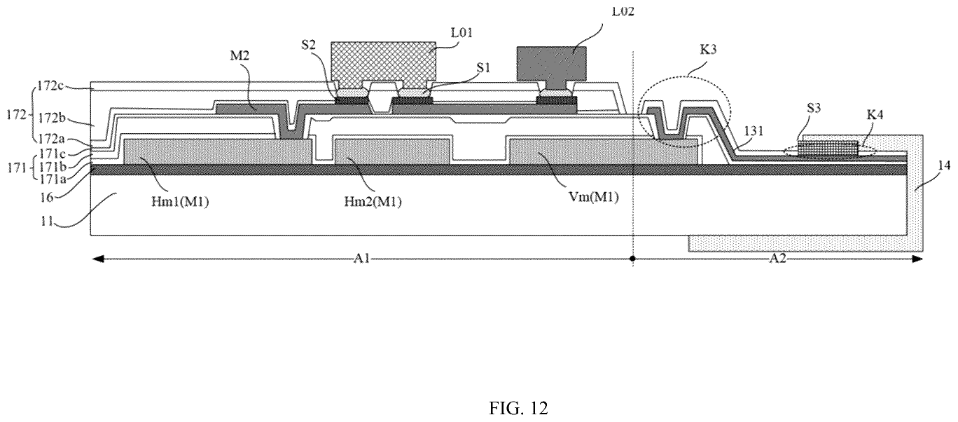

In an exemplary embodiment, referring to FIG. 11 and FIG. 12, FIG. 11 is a schematic structure diagram of a top view of another display panel according to some embodiments of the present disclosure. FIG. 12 is a schematic structure diagram of a cross-section of the display panel shown in FIG. 11 (FIG. 12 may be a schematic structure diagram of a cross-section of the display panel shown in FIG. 11 at G3-G3). The first surface wiring 12 may include various wirings disposed in the display region A1 of the first surface A. Exemplarily, the display region A1 of the display panel 10 may include a first wiring layer M1 and a second wiring layer M2 stacked in a direction away from the substrate 11. The first surface wiring 12 includes conductive patterns disposed in the first wiring layer M1 and/or the second wiring layer M2. In the display region A1, the display panel 10 also includes a second buffer layer 171a, a first organic layer 171b, a first passivation layer 171c, a third buffer layer 172a, a second organic layer 172b, and a second passivation layer 172c. The second buffer layer 171a, the first organic layer 171b, and the first passivation layer 171c are disposed between the first wiring layer M1 and the second wiring layer M2 and are sequentially stacked in a direction away from the substrate 11. The third buffer layer 172a, the second organic layer 172b, and the second passivation layer 172c are disposed on a side of the second wiring layer M2 away from the first wiring layer M1 and are sequentially stacked in a direction away from the substrate 11. The first retaining wall structure 15 is disposed at least between any two adjacent electrode structures 13, and at least two of the plurality of cross-sections of the first retaining wall structure 15 parallel to the first surface A have different areas.

The second buffer layer 171a and the third buffer layer 172a can increase the bonding force between the film layers, and can also block the first surface wiring 12 from water and oxygen corrosion. The first passivation layer 171c and the second passivation layer 172c can serve as insulation, and can protect the first surface wiring from water and oxygen corrosion. Exemplarily, materials of the second buffer layer 171a, the third buffer layer 172a, the first passivation layer 171c, and the second passivation layer 172c may include silicon nitride, and/or, silicon oxide. The manufacturing process for the second buffer layer 171a, the third buffer layer 172a, the first passivation layer 171c, and the second passivation layer 172c may include plasma-enhanced chemical vapor deposition (PECVD). The first organic layer 171b and the second organic layer 172b may perform a planarization function, such that the flatness of the surface of the film layer may be improved. Exemplarily, the material of both the first organic layer 171b and the second organic layer 172b may include a resin material, such as a polyimide or a polyacrylic acid.

The first passivation layer 171c is disposed on a side of the electrode structure 13 close to the substrate 11, the first passivation layer 171c may include an adapter hole K3, and the electrode structure 13 may be adapted to the first surface wiring 12 through the adapter hole K3. The second passivation layer 172c is disposed on the side of the electrode structure 13 away from the substrate 11, the second passivation layer 172c may include a through-hole K4, and the electrode structure 13 may be electrically connected to the side wiring 14 through the through-hole K4. The conductive structure S3 is disposed within the through-hole K4 and covers the electrode structure 13, and the conductive structure S3 is used to protect the surface-exposed region of the electrode structure 13 from corrosion of the electrode structure 13 by water vapor in the air. Exemplarily, the material of the conductive structure S3 may include nickel, and/or, gold. In addition, the first wiring layer M1 may include a first positive signal line Hm1, a second positive signal line Hm2, a reference signal line Vm, a data signal line Dm, and a scanning signal adapter line Cn. The second wiring layer M2 may include a plurality of scanning signal lines Sn, each of which may be electrically connected to one scanning signal adapter line Cn. A driving element L02 may be electrically connected to a cathode of a light-emitting element L01 in each sub-pixel driven by the driving element L02, at least one data signal line Dm of a plurality of data lines, at least one scanning signal line Sn of the plurality of scanning signal lines, and at least one reference signal line Vm of the plurality of reference signal lines. The reference signal line Vm may supply a negative signal to the driving element L02 to form a current path between the driving element L02 and the light-emitting element L01. The driving element L02 may be configured to time-write signals from the data signal line Dm into sub-pixels of different colors under the control of the scanning signal line Sn. In addition, a pin of the light-emitting element L01 and a pin of the driving element L02 may be electrically connected to a corresponding connection pad through a solder material S1 (e.g., solder, tin-silver-copper alloy, or tin-copper alloy, etc.), and the connection pad may also include a protective layer S2. The pin of the light-emitting element L01 may be electrically connected to the connection pad through a via passing through the second buffer layer 171a, the first organic layer 171b, and the first passivation layer 171c, and the pin of the driving element L02 may be connected to the connection pad through a via passing through the third buffer layer 172a, the second organic layer 172b, and the second passivation layer 172c, such that the light-emitting element L01 is capable of emitting light under the signals transmitted by the signal line and under the control of the driving element L02.

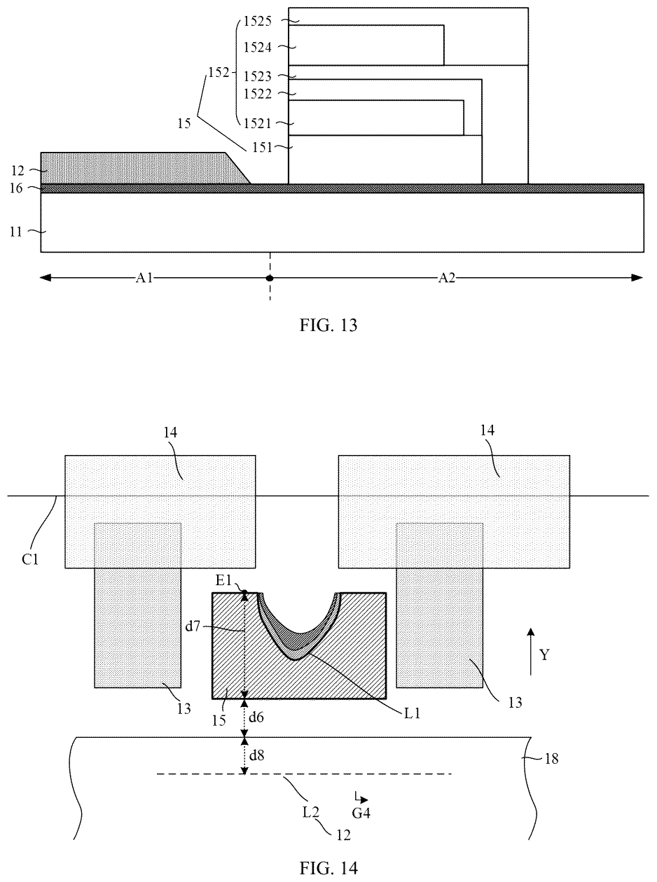

In an exemplary embodiment, the plurality of stacked film layers in the first retaining wall structure may be of the same layer structure as some insulated film layers in the display region to achieve the effect of reducing the composition process. Exemplarily, referring to FIG. 11, FIG. 12, and FIG. 13, FIG. 13 is a schematic structure diagram of a cross-section of a partial structure of another display panel according to some embodiments of the present disclosure. The first retaining wall structure 15 includes a protective layer 151, a first film layer 1521, a second film layer 1522, a third film layer 1523, a fourth film layer 1524, and a fifth film layer 1525 sequentially stacked along a direction away from the substrate 11. The protective layer 151 is of the same layer structure as the second buffer layer 171a, the first film layer 1521 is of the same layer structure as the first organic layer 171b, the second film layer 1522 is of the same layer structure as the first passivation layer 171c, the third film layer 1523 is of the same layer structure as the third buffer layer 172a, the fourth film layer 1524 is of the same layer structure as the second organic layer 172b, and the fifth film layer 1525 is of the same layer structure as the second passivation layer 172c. By being provided in the same layer with some of the film layers in the display region A1 to form the first retaining wall structure 15, not only the effect of blocking the conductive material of the side wiring can be achieved, but also the process can be simplified and the cost can be saved. In addition, FIG. 13 illustrates the first retaining wall structure 15 including six stacked film layers. For a display panel provided with different driving methods, the number and type of the film layers included in the first retaining wall structure 15 may be different, and exemplarily, the first retaining wall structure 15 may also include three film layers, four film layers, five film layers, or seven film layers, which is not limited in the embodiments of the present disclosure.

In the first retaining wall structure 15, the second file layer 1522 may cover an edge of the first film layer 1521 close to the side surface, and the fifth film layer 1525 may cover an edge of the fourth film layer 1524 close to the side surface, thereby preventing the edges of the plurality of film layers close to the side surface in the first retaining wall structure 15 from peeling off. In addition, the relative positions of the edges of the plurality of film layers close to the side surfaces in the first retaining wall structure 15 include various cases. For example, in the first retaining wall structure 15, the edge of the first film layer 1521 close to the side surface may be disposed on a side, close to the edge of the side surface away from the edge of the substrate, of the protective layer 151, or an edge of the second film layer 1522 close to the side surface may be disposed on a side, close to the edge of the side surface away from the edge of the substrate, of the protective layer 151, or an edge of the third film layer 1523 close to the side surface may be disposed on a side, close to the side surface away from the edge of the substrate, of the fifth film layer 1525, which is not limited in the embodiments of the present disclosure.

The above is a case where the first retaining wall structure is a multi-layer structure, and the first retaining wall structure may also be a single-layer structure. The single-layer structure of the first retaining wall structure may be independently manufactured, and exemplarily, the first retaining wall structure may include a target film layer that is independently manufactured, and the thickness of the target film layer in a direction perpendicular to the substrate may range from 3 μm to 6 μm, and the material of the target film layer may include a material having water-oxygen resistance, such as silicon oxide or silicon nitride. In this way, the first retaining wall structure can not only effectively block the conductive material of the side wiring from entering the display region, but also protect the first surface wiring from water and oxygen corrosion. In addition, the target film layer can be manufactured by the composition process, and the composition process involved in the embodiments of the present disclosure can include coating photoresist, exposure, developing, etching, and stripping photoresist.

In an exemplary embodiment, the display panel may further include a second retaining wall structure. Referring to FIG. 14 and FIG. 15, FIG. 14 is a schematic structure diagram of a top view of a partial structure of another display panel according to some embodiments of the present disclosure, and FIG. 15 is a schematic structure diagram of a cross-section of the display panel shown in FIG. 14 (FIG. 15 is a schematic structure diagram of a cross-section of the display panel shown in FIG. 14 at G4-G4). The display panel 10 includes a substrate 11, a first surface wiring 12, a plurality of electrode structures 13, a side wiring 14, and a first retaining wall structure 15. The first retaining wall structure 15 is disposed at least between any two adjacent electrode structures 13, and at least two of the plurality of cross-sections of the first retaining wall structure 15 parallel to the first surface A have different areas. The first retaining wall structure 15 includes a protective layer 151, a first film layer 1521, a second film layer 1522, a third film layer 1523, a fourth film layer 1524, and a fifth film layer 1525 sequentially stacked along a direction away from the substrate 11.

The display panel 10 also includes a second retaining wall structure 18. The second retaining wall structure 18 is disposed on a side of the first retaining wall structure 15 away from the side wiring 14 and covers an edge of the first surface wiring 12 close to the side wiring 14, such that the second retaining wall structure 18 can prevent water and oxygen from causing corrosion of the first surface wiring 12. The second retaining wall structure 18 may include a plurality of film layers sequentially stacked along a direction away from the substrate 11. The plurality of film layers of the second retaining wall structure 18 may be independently manufactured.

In addition, the plurality of film layers of the second retaining wall structure 18 may also be the same film layers as some of the film layers in the display region to achieve the effect of reducing the composition process. Referring to FIG. 12 and FIG. 15, i.e., the second retaining wall structure 18 may include a second buffer layer 171a, a first organic layer 171b, a first passivation layer 171c, a third buffer layer 172a, a second organic layer 172b, and a second passivation layer 172c. Alternatively, the second retaining wall structure 18 may be the single-layer structure, and may include a single-layer that is independently manufactured, which is not limited in the embodiments of the present disclosure.

In some embodiments, a spacing d6 is present between the first retaining wall structure 15 and the second retaining wall structure 18, i.e., the first retaining wall structure 15 and the second retaining wall structure 18 are separate and discontinuous. In the case that the film layer in the first retaining wall structure 15 peels off due to etching, the film layers in the first retaining wall structure 15, the second retaining wall structure and the display region may be prevented from bulging due to the separation of the first retaining wall structure 15 and the second retaining wall structure 18, thereby avoiding corrosion of the first surface wiring 12 due to bulging of the film layers.

In some embodiments, the spacing d6 between the first retaining wall structure 15 and the second retaining wall structure 18 may range from 10 μm to 110 μm. Considering the reason of process precision, in the range, by setting d6 greater than or equal to 10 μm, it can be ensured that the first retaining wall structure 15 is separated from the second retaining wall structure 18. By setting d6 less than or equal to 110 μm, it can be ensured that a size d7 of the first retaining wall structure 15 in the second direction Y is greater than or equal to 30 μm, such that the first retaining wall structure 15 can block the conductive material of the side wiring 14. In addition, the size of the first retaining wall structure 15 in the second direction Y is d7, and a minimum distance between the edge of the second retaining wall structure 18 close to the side surface and the second contour L2 in the second direction Y is d8. The d7 and d8 may be determined based on the minimum distance d2 between the first position E1 of the first contour L1 and the second contour L2. Exemplarily, the size d7 of the first retaining wall structure 15 in the second direction Y may range from 30 μm to 130 μm. The minimum distance d8 between the edge of the second retaining wall structure 18 close to the side surface and the second contour L2 in the second direction Y may range from 10 μm to 100 μm.

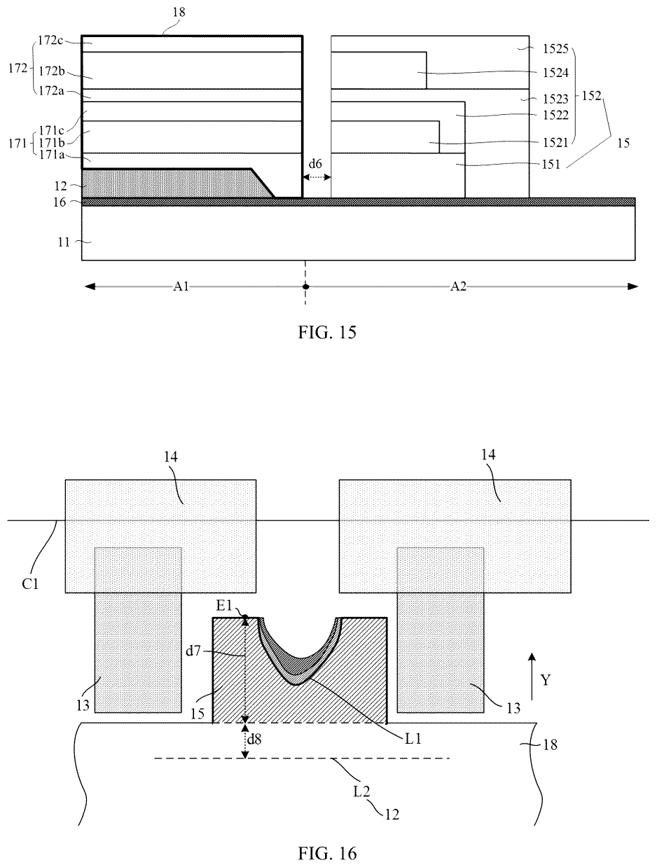

FIG. 14 and FIG. 15 illustrate a case where the first retaining wall structure is separated from the second retaining wall structure, and the first retaining wall structure and the second retaining wall structure also include another case. Referring to FIG. 16, FIG. 16 is a schematic structure diagram of a top view of a partial structure of another display panel according to some embodiments of the present disclosure. A second retaining wall structure 18 is disposed on a side of a first retaining wall structure 15 away from a side wiring 14, and the first retaining wall structure 15 is connected to the second retaining wall structure 18. For the display panel illustrated in FIG. 16, as the first retaining wall structure 15 is connected to the second retaining wall structure 18, no spacing is present between the first retaining wall structure 15 and the second retaining wall structure 18, and thus a maximum size d7 of the first retaining wall structure 15 in the second direction Y may range from 40 μm to 140 μm.

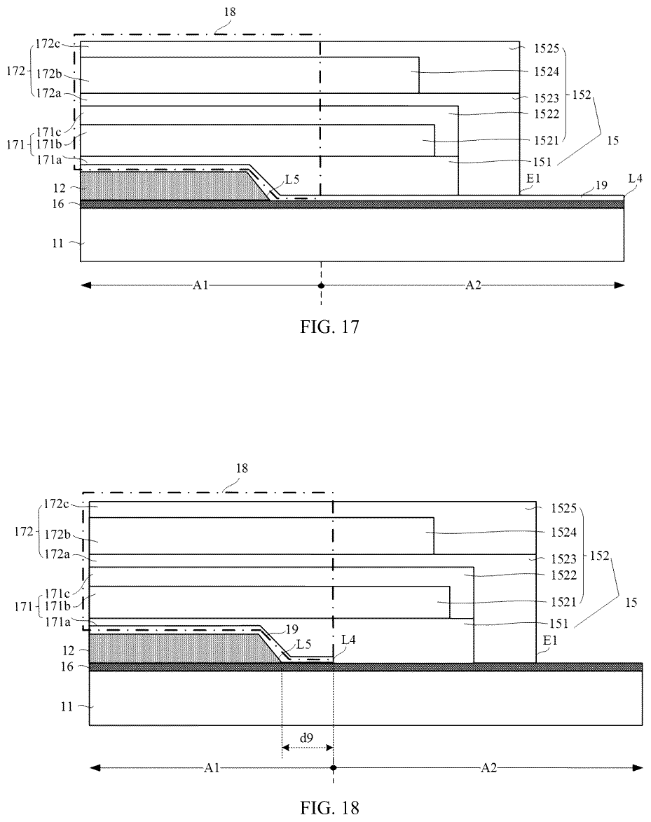

In an exemplary embodiment, the display panel may also include a fourth buffer layer. Referring to FIG. 17, FIG. 17 is a schematic structure diagram of a cross-section of a partial structure of another display panel according to some embodiments of the present disclosure. The display panel 10 includes a first retaining wall structure 15 and a second retaining wall structure 18. The second retaining wall structure 18 is disposed on a side of the first retaining wall structure 15 away from a side wiring, and the first retaining wall structure 15 is connected to the second retaining wall structure 18.

The display panel 10 further includes a fourth buffer layer 19. The fourth buffer layer 19 is disposed between the first surface wiring 12 and the first retaining wall structure 15 and may improve the bonding force between the first surface wiring 12 and the first retaining wall structure 15. The material of the fourth buffer layer 19 may include silicon nitride and/or silicon oxide treated with silane (SiH₄), such that the adhesion of the fourth buffer layer 19 is improved. The silane treatment is a treatment in which silane is added to a material to form partial covalent bonds in the material, and the silane treatment may be used to improve the adhesion of the material.

In addition, the relative positions between an edge of the fourth buffer layer 19 close to the side surface and the edge of the first retaining wall structure 15 close to the side surface include various cases. Exemplarily, referring to FIG. 17, an edge L4 of a fourth buffer layer 19 close to the side surface may be flush with the edge of the substrate 11, and the thickness of the fourth buffer layer 19 in the direction perpendicular to the substrate 11 may be less than 3000 angstroms (A).

In addition, referring to FIG. 18, FIG. 18 is a schematic structure diagram of a cross-section of a partial structure of another display panel according to some embodiment of the present disclosure. The display panel 10 includes a first retaining wall structure 15 and a second retaining wall structure 18, the second retaining wall structure 18 is disposed on a side of the first retaining wall structure 15 away from the side of the side wiring, and the first retaining wall structure 15 is connected to the second retaining wall structure 18. The display panel 10 further includes a fourth buffer layer 19, an edge L4 of the fourth buffer layer 19 close to the side surface is disposed on a side of a first position E1 of the first retaining wall structure 15 away from the side surface, and a minimum distance d9 between an edge L4 of the fourth buffer layer 19 close to the side surface and an edge L5 of a first surface wiring 12 close to the side surface may be greater than or equal to 20 μm, so as to ensure that the fourth buffer layer 19 can cover the edge L5 of the first surface wiring 12 close to the side surface, then the fourth buffer layer 19 can also serve to protect the first surface wiring 12 from water and oxygen corrosion of the first surface wiring 12.

In summary, the embodiments of the present disclosure provide a display panel including a first retaining wall structure and a display device. In the display panel, the first retaining wall structure is disposed at least between any two adjacent electrode structures, and at least two of a plurality of cross-sections of the first retaining wall structure parallel to the first surface have different areas. The cross-sections of the first retaining wall structure having different areas are formed by laser etching, such that at least a portion of the conductive material piled up at the first retaining wall structure during the formation of the side wiring can be removed by laser etching to avoid that the piled up conductive material causes a short circuit of the adjacent electrode structures, and thus a yield of the display panel is improved.

In another aspect, the embodiments of the present disclosure provide a display device which may include a display structure and the above-described display panel, the display structure is disposed on the display panel. As the display device includes the display panel provided in the above embodiments, the display device can in turn have a similar effect, i.e., the display effect of the display device can be improved.

The term “and/or” in the present disclosure is merely a description of an association relationship of the associated objects, indicating that three relationships may exist, e.g., A and/or B, which may represent three cases: A exists alone, both A and B exist, and B exists alone. In addition, the character “/” in this paper generally indicates that the associated objects before and after are in an “or” relationship.

The term “at least one of A and B” in the present disclosure is merely a description of an association relationship of an associated object, and indicates that three relationships may exist, for example, at least one of A and B may be indicated as: A exists alone, both A and B exist, and B exists alone. Similarly, “at least one of A, B, and C” indicates that seven relationships may exist, which can be expressed as follows: A exists alone, B exists alone, C exists alone, both A and B exist, both A and C exist, both C and B exist, and all A, B, and C exist. Similarly, “at least one of A, B, C and D” indicates that fifteen relationships may exist, which can be expressed as follow: A exists alone, B exists alone, C exists alone, D exists alone, both A and B exist, both A and C exist, both A and D exist, both C and B exist, both D and B exist, both C and D exist, both A and B exist, both A and B exist, both A and B exist, both D and C exist, both C and D exist, all A, B and C exist, all A, B and C exist, all A, B and D exist, all A, C and D exist, all B, C and D exist, all A, B, C and D exist, which are the fifteen cases.

It should be noted that in the accompanying drawings, the sizes of the layers and regions may be exaggerated for the sake of clarity of the illustrations. Moreover, it is understood that an element or layer is referred to as being “on” another element or layer, it may be directly on the other element, or there may be intermediate layers. Also, it is to be understood that when the element or layer is referred to as being “under” another element or layer, it may be directly under the other element, or more than one intermediate layer or element may exist. It is also understood that a layer or element is referred to as being “between” two layers or elements, it may be the only layer between the two layers or elements, or more than one intermediate layer or element may also exist. Similar reference marks throughout indicate similar elements.

In the present disclosure, the terms “first,” “second,” “third,” “fourth,” “fifth,” “sixth,” “seventh,” “eighth,” “ninth,” “tenth,” and “eleventh” are merely used for descriptive purposes and should not be construed as indicating or implying the relative importance. The term “a plurality of” refers to two or more, unless otherwise explicitly defined

Described above are merely optional embodiments of the present disclosure, and are not intended to limit the present disclosure. Within the spirit and principles of the present disclosure, any modifications, equivalent substitutions, improvements, and the like should fall within the scope of protection of the present disclosure.

1. A display panel, comprising a substrate, a first surface wiring, an electrode structure, a plurality of side wirings, and a first retaining wall structure,
wherein the substrate has a first surface and a second surface which are opposite, and a plurality of side surfaces connected to the first surface and the second surface, the first surface comprising a display region and a peripheral region surrounding the display region;
the first surface wiring is disposed on the display region of the first surface, the electrode structure is disposed on the peripheral region of the first surface, and the plurality of side wirings are disposed on at least one of the plurality of side surfaces; wherein one end of each of the plurality of side wirings is electrically connected to the electrode structure and another end extends sequentially through the first surface and the at least one of the plurality of side surfaces to the second surface, and the electrode structure is further electrically connected to the first surface wiring; and a plurality of the electrode structures are defined and are spaced apart along a first direction, the first direction being a direction parallel to the at least one of the plurality of side surfaces; and
the first retaining wall structure is disposed at least between any two adjacent electrode structures, wherein at least two of a plurality of cross-sections of the first retaining wall structure parallel to the first surface have different areas; wherein a cross-section with a smallest area of the plurality of cross-sections is a first cross-section, an orthographic projection of the first cross-section on the first surface has a first contour, and an orthographic projection of the first surface wiring on the first surface has a second contour, a minimum distance d1 between the first contour and the second contour in a second direction is not less than 10 μm, the second direction being perpendicular to the first direction.

2. The display panel according to claim 1, wherein in the second direction, the first contour and the second contour satisfy that a ratio of d2 to d3 is greater than ½ and less than 3, wherein the d2 is a minimum distance between a first position of the first contour and the second contour, and the d3 is a minimum distance between an edge of the electrode structure away from the side wiring and the second contour, the first position being a position of the first contour which is furthest away from the second contour.

3. The display panel according to claim 2, wherein in the second direction, the first contour and the second contour satisfy that the ratio of d2 to d3 is greater than 1 and less than 3.

4. The display panel according to claim 1, wherein the first retaining wall structure comprises a plurality of stacked film layers, a thickness of the plurality of stacked film layers in a direction perpendicular to the substrate ranging from 3 μm to 6 μm.

5. The display panel according to claim 4, wherein the first retaining wall structure comprises a protective layer and at least one film layer, wherein the protective layer is disposed on the substrate where the first surface wiring is formed, and an edge of the protective layer close to the side wiring is disposed on a side of the first surface wiring close to the side wiring, and the at least one film layer is stacked on the protective layer.

6. The display panel according to claim 5, wherein in the second direction, a position of the protective layer closest to the side surface is a second position, and a position of the at least one film layer closest to the side surface is a third position;
wherein in the second direction, the third position is disposed on a side of the second position close to the side surface.

7. The display panel according to claim 6, wherein a specified distance is present between the third position and the second position in the second direction, the specified distance ranging from 20 μm to 100 μm.

8. The display panel according to claim 1, wherein the first retaining wall structure comprises a target film layer, a thickness of the target film layer in a direction perpendicular to the substrate ranging from 3 μm to 6 μm.

9. The display panel according to claim 1, wherein in the second direction, a minimum distance between a first position of the first contour and the second contour ranges from 50 μm to 150 μm, the first position being a position of the first contour furthest away from the second contour.

10. The display panel according to claim 1, further comprising a second retaining wall structure, wherein the second retaining wall structure is disposed on a side of the first retaining wall structure away from the side wiring, and the second retaining wall structure covers an edge of the first surface wiring close to the side wiring.

11. The display panel according to claim 10, wherein the first retaining wall structure is connected to the second retaining wall structure.

12. The display panel according to claim 10, wherein a spacing is present between the first retaining wall structure and the second retaining wall structure.

13. The display panel according to claim 12, wherein the spacing between the first retaining wall structure and the second retaining wall structure ranges from 10 μm to 110 μm.

14. The display device, comprising a display structure and a display panel, wherein the display structure is disposed on the display panel; and
the display panel comprises a substrate, a first surface wiring, an electrode structure, a plurality of side wirings, and a first retaining wall structure,
wherein the substrate has a first surface and a second surface which are opposite, and a plurality of side surfaces connected to the first surface and the second surface, the first surface comprising a display region and a peripheral region surrounding the display region;
the first surface wiring is disposed on the display region of the first surface, the electrode structure is disposed on the peripheral region of the first surface, and the plurality of side wirings are disposed on at least one of the plurality of side surfaces; wherein one end of each of the plurality of side wirings is electrically connected to the electrode structure and another end extends sequentially through the first surface and the at least one of the plurality of side surfaces to the second surface, and the electrode structure is further electrically connected to the first surface wiring; and a plurality of the electrode structures are defined and are spaced apart along a first direction, the first direction being a direction parallel to the at least one of the plurality of side surfaces; and
the first retaining wall structure is disposed at least between any two adjacent electrode structures, wherein at least two of a plurality of cross-sections of the first retaining wall structure parallel to the first surface have different areas; wherein a cross-section with a smallest area of the plurality of cross-sections is a first cross-section, an orthographic projection of the first cross-section on the first surface has a first contour, and an orthographic projection of the first surface wiring on the first surface has a second contour, a minimum distance d1 between the first contour and the second contour in a second direction is not less than 10 μm, the second direction being perpendicular to the first direction.

15. The display panel according to claim 5, wherein in the second direction, a position of the protective layer closest to the side surface is a second position, and a position of the at least one film layer closest to the side surface is a third position;
wherein in the second direction, the second position and the third position are flush.

16. The display device according to claim 14, wherein in the second direction, the first contour and the second contour satisfy that a ratio of d2 to d3 is greater than ½ and less than 3, wherein the d2 is a minimum distance between a first position of the first contour and the second contour, and the d3 is a minimum distance between an edge of the electrode structure away from the side wiring and the second contour, the first position being a position of the first contour which is furthest away from the second contour.

17. The display device according to claim 16, wherein in the second direction, the first contour and the second contour satisfy that the ratio of d2 to d3 is greater than 1 and less than 3.

18. The display device according to claim 14, wherein the first retaining wall structure comprises a plurality of stacked film layers, a thickness of the plurality of stacked film layers in a direction perpendicular to the substrate ranging from 3 μm to 6 μm.

19. The display device according to claim 18, wherein the first retaining wall structure comprises a protective layer and at least one film layer, wherein the protective layer is disposed on the substrate where the first surface wiring is formed, and an edge of the protective layer close to the side wiring is disposed on a side of the first surface wiring close to the side wiring, and the at least one film layer is stacked on the protective layer.

20. The display device according to claim 19, wherein in the second direction, a position of the protective layer closest to the side surface is a second position, and a position of the at least one film layer closest to the side surface is a third position;
wherein in the second direction, the third position is disposed on a side of the second position close to the side surface.
